(19) United States
(12) Patent Application Publication
(10) Pub. No.: US 2023/0017876 A1
(43) Pub. Date: Jan. 19, 2023

(54) PLASMA PROCESSING APPARATUS AND PLASMA PROCESSING METHOD

(71) Applicant: Tokyo Electron Limited, Minato-ku, Tokyo (JP)

(72) Inventor: Toshihiko IWAO, Austin, TX (US)

(21) Appl. No.: 17/757,781

(22) PCT Filed: Dec. 16, 2020
(86) PCT No.: PCT/JP2020/046978

§ 371 Date: Jun. 21, 2022

(30) Foreign Application Priority Data
Dec. 25, 2019 (JP) 2019-234695

(51) Int. Cl. H01J 37/32; H01P 3/12; C23C 16/509

(52) U.S. Cl. CPC H01J 37/32082; H01J 37/32568; H01P 3/12; C23C 16/509; H01J 2237/3323

(57) ABSTRACT

A plasma processing apparatus for processing an object to be processed with plasma, includes: a stage on which the object to be processed is placed; an electrode arranged at a position facing the stage and to which high-frequency power having a frequency of 30 MHz or more is supplied; and a waveguide configured to propagate electromagnetic waves generated based on the high-frequency power to a plasma processing space formed between the stage and the electrode, wherein the waveguide is formed in an annular shape in a plan view so that an end portion of the waveguide near the plasma processing space surrounds an outer periphery of the electrode, a plurality of pins are provided to protrude into the waveguide, and the plurality of pins are arranged at respective positions separated from one another along a circumferential direction in the plan view.

### TECHNICAL FIELD

The present disclosure relates to a plasma processing apparatus and a plasma processing method.

### BACKGROUND

Patent Document 1 discloses a plasma processing apparatus that performs predetermined plasma processing on a substrate to be processed. In this plasma processing apparatus, an upper electrode includes an electrode plate provided to face a lower electrode, and the electrode plate includes an outer portion made of a conductor or a semiconductor and a central portion made of a dielectric member or a high-resistance member having a resistance higher than that of the outer portion. High-frequency power is supplied to the upper electrode from a surface opposite to the lower electrode. In Patent Document 1, the frequency of the supplied high-frequency power is 27 MHz or more.

### PRIOR ART DOCUMENT

### Patent Document

Patent Document 1: Japanese Laid-Open Patent Publication No. 2000-323456

The technique according to the present disclosure improves the uniformity of processing results in a circumferential direction and the like when plasma processing is performed using plasma generated based on high-frequency power of 30 MHz or more.

### SUMMARY

An aspect of the present disclosure relates to a plasma processing apparatus for processing an object to be processed with plasma. The plasma processing apparatus includes: a stage on which the object to be processed is placed; an electrode arranged at a position facing the stage and to which high-frequency power having a frequency of 30 MHz or more is supplied; and a waveguide configured to propagate electromagnetic waves generated based on the high-frequency power to a plasma processing space formed between the stage and the electrode, wherein the waveguide is formed in an annular shape in a plan view so that an end portion of the waveguide near the plasma processing space surrounds an outer periphery of the electrode, a plurality of pins are provided to protrude into the waveguide, and the plurality of pins are arranged at respective positions separated from one another along a circumferential direction in a plan view.

According to the present disclosure, it is possible to improve the uniformity of processing results in a circumferential direction and the like when plasma processing is performed using plasma generated based on high-frequency power of 30 MHz or more.

### BRIEF DESCRIPTION OF DRAWINGS

FIG. 1 is a view schematically illustrating an example of plasma processing results in a plasma processing apparatus in the related art.

FIG. 2 is a view schematically illustrating another example of plasma processing results in a plasma processing apparatus in the related art.

FIG. 3 is a vertical cross-sectional view schematically illustrating an outline of a configuration of a film forming apparatus as a plasma processing apparatus according to an embodiment.

FIG. 4 is a partially enlarged view of FIG. 3.

FIG. 5 is a view illustrating an arrangement of pins in which a processing container is illustrated in a cross section.

FIG. 6 is a view schematically illustrating a distribution of electric field strength of electromagnetic waves propagating in a plasma processing space directly under a dielectric window, in which the distribution when no pin is provided is illustrated.

FIG. 7 is a view schematically illustrating the distribution of electric field strength of electromagnetic waves propagating in the plasma processing space directly under the dielectric window, in which the distribution when pins are provided is illustrated.

FIG. 8 is a top view of the plasma processing space, illustrating simulation conditions.

FIG. 9 is a view illustrating simulation results on an effect of the number of pins and an arrangement angle of the pins.

FIG. 10 is a view illustrating simulation results of an electric field distribution at pin arrangements positions.

FIG. 11 is a view illustrating simulation results on an effect of a path length from the plasma processing space to the pins.

### DETAILED DESCRIPTION

As processing in a process of manufacturing a semiconductor or the like, there is plasma processing in which film formation or etching is performed on an object to be processed, such as a semiconductor wafer (hereinafter referred to as “wafer”), by using plasma. In the plasma processing, it is preferable to use plasma having a high density and a low electron temperature from the viewpoints of shortening a processing time and reducing damage to the object to be processed. In order to generate such high-density and low-electron temperature plasma, high-frequency power in the VHF band or the like may be used. In Patent Document 1, high-frequency power of 27 MHz or higher is supplied for plasma generation.

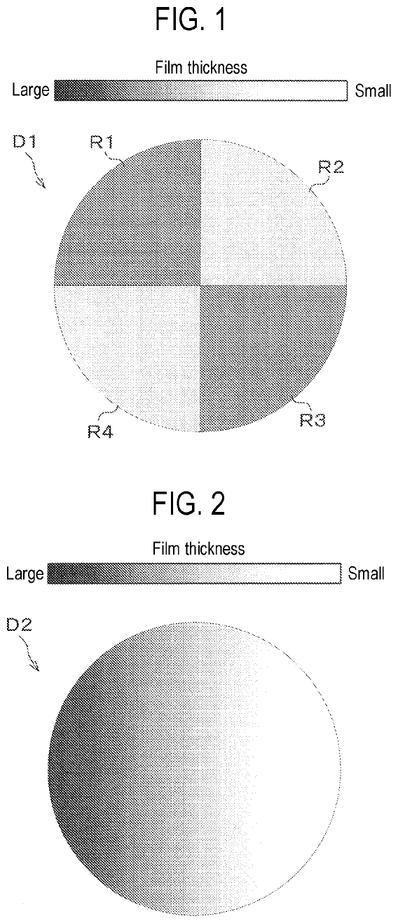

However, when high-frequency power in the VHF band or the like is used for plasma generation, there is room for improvement in terms of in-plane uniformity of plasma processing results. Specifically, in a configuration of an apparatus in the related art, when film formation is performed using high-frequency power in the VHF band or the like, a film thickness distribution D1 may be in a double symmetry relationship as illustrated in FIG. 1. In the film thickness distribution of FIG. 1, when the substrate is divided into four portions along the circumferential direction, the film thickness is large in regions R1 and R3 facing each other at one side, and the film thickness is small in regions R2 and R4 facing each other at the other side. In order to further improve the in-plane uniformity of the film thickness, it is necessary to eliminate the above-mentioned the double symmetry relationship. That is, there is room for improvement in the uniformity of the film thickness distribution in the circumferential direction. In addition, as illustrated in FIG. 2, a film thickness distribution D2 may be a one-sided film thickness distribution. In the film thickness distribution D2 in FIG. 2, the film thickness gradually decreases from the peripheral end at one side in a substrate width direction (the left side in the drawing) to the peripheral end at the other side in the substrate width direction (the right side in the drawing). In order to further improve the in-plane uniformity of the film thickness, it is necessary to eliminate this one-sided distribution.

Patent Document 1 does not disclose this point.

The technique according to the present disclosure improves the uniformity of processing results in the circumferential direction and the like when plasma processing is performed by using plasma generated based on high-frequency power of 30 MHz or more of the VHF band or the like.

Hereinafter, a configuration of a plasma processing apparatus according to the present embodiment will be described with reference to the drawings. In this specification, elements having substantially the same functional configurations will be denoted by the same reference numerals and redundant descriptions thereof will be omitted.

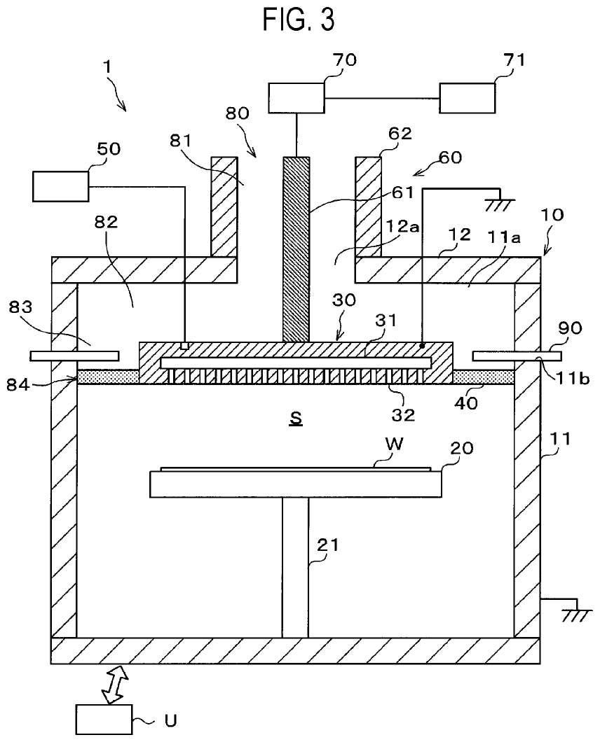

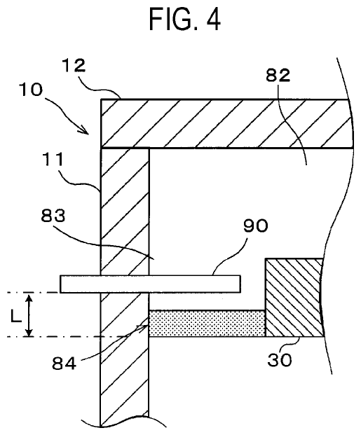

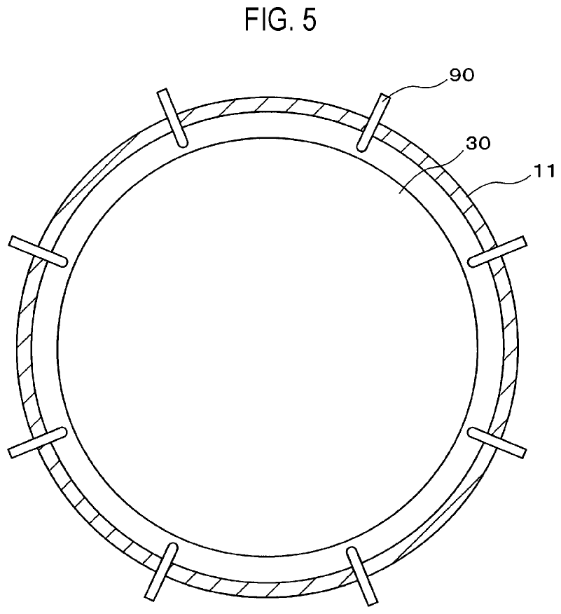

FIG. 3 is a vertical cross-sectional view schematically illustrating an outline of a configuration of a film forming apparatus 1 as a plasma processing apparatus according to an embodiment. FIG. 4 is a partially enlarged view of FIG. 3. FIG. 5 is a view illustrating an arrangement of pins to be described later in which a processing container to be described later is illustrated in a cross section.

The film forming apparatus 1 of FIG. 3 is for forming a film on a wafer W as an object to be processed through plasma processing. In the film forming apparatus 1, the plasma used for plasma processing is generated based on high-frequency power of 30 MHz or more. The film forming apparatus 1 forms, for example, a SiN film.

The film forming apparatus 1 includes a processing container 10 in which a plasma processing space S is formed. In the processing container 10, the plasma processing space is formed between a stage to be described later and a shower head provided inside the processing container 10.

The processing container 10 includes a container main body 11 and a lid 12. The container main body 11 and the lid 12 are made of aluminum or the like and are electrically connected to a ground potential. In the processing container 10, at least a portion of the container main body 11 exposed to plasma is covered with a liner (not illustrated) on which a thermal spray coating including a plasma-resistant material is formed.

The container main body 11 is formed in a hollow shape having an opening 11a. Specifically, the container main body 11 is formed in a bottomed cylindrical shape having an opening 11a at the top. The central axis of the sidewall of the container main body 11 coincides with the central axis of the container main body 11. Although not illustrated, an exhaust device is connected to the bottom of the container main body 11 via an APC valve (not illustrated) or the like in order to depressurize the processing container 10, specifically, to depressurize the plasma processing space S.

The lid 12 is formed in a disk shape having a through-hole 12a in the center. The lid 12 is installed on the upper side of the container main body 11 to block the opening 11a of the container main body 11. The central axes of the lid 12 and the through-hole 12a coincide with the central axis of the container main body 11.

Below the plasma processing space S inside the processing container 10, a stage 20, on the top surface of which the wafer W is horizontally placed, is provided.

The stage 20 is supported by a support member 21 provided upright on the center of the bottom of the container main body 11. Although not illustrated, the stage 20 is provided with a heater for heating the wafer W. Instead of a heating mechanism such as a heater, a cooling mechanism including a coolant flow path or the like through which a cooling coolant flows may be provided, or both the heating mechanism and the cooling mechanism may be provided. In addition, substrate support pins (not illustrated) are provided to be vertically movable with respect to the stage 20. The substrate support pins are for delivering the wafer W between a wafer transfer device (not illustrated) introduced into the processing container 10 from the exterior of the processing container 10 and the stage 20.

A shower head electrode 30 is provided above the plasma processing space S of the stage 20 inside the processing container 10 at a position facing the stage 20.

The shower head electrode 30 is formed of a conductive material, specifically, a metal material such as aluminum, and has a disk shape. A distance from the bottom surface of the shower head electrode 30 to the top surface of the stage 20 is, for example, 150 mm.

The shower head electrode 30 is supported by the processing container 10 via a dielectric window 40. An upper space and a lower space inside the processing container 10 are separated by the shower head electrode 30 and the dielectric window 40. The interior of the processing container 10 is sealed by the shower head electrode 30 and the dielectric window 40 such that only the above-mentioned lower space is depressurized when the interior of the processing container 10 is depressurized by the above-mentioned exhaust device. The central axis of the shower head electrode 30 coincides with the central axis of the container main body 11. The details of the dielectric window 40 will be described later.

Inside the shower head electrode 30, a gas diffusion chamber 31 formed in a substantially disk-like shape is provided. A plurality of gas ejection ports 32 communicating with the gas diffusion chamber 31 are provided in the lower portion of the shower head electrode 30, that is, the portion on the plasma processing space S side. A gas source 50 provided outside the processing container 10 is connected to the gas diffusion chamber 31. A plasma processing gas from the gas source 50 is supplied to the gas diffusion chamber 31 and ejected to the plasma processing space S through the gas ejection ports 32.

The dielectric window 40 is provided to cover the outer peripheral surface of the shower head electrode 30, and also transmits, to the plasma processing space S, electromagnetic waves which are based on high-frequency power and propagate through the waveguide 80 to be described later.

The film forming apparatus 1 further includes a coaxial waveguide 60. The coaxial waveguide 60 has an inner conductor 61 and an outer conductor 62.

One end of the inner conductor 61 is connected to the center of the top surface of the shower head electrode 30. The central axis of the inner conductor 61 coincides with the central axis of the container main body 11. The other end of the inner conductor 61 is connected to a high-frequency power supply 71 via a matcher 70. The high-frequency power from the high-frequency power supply 71 is supplied to the shower head electrode 30 via the matcher 70. The high-frequency power supply 71 outputs high-frequency power of 30 MHz or more, specifically, high-frequency power in the VHF band (30 MHz to 300 MHz) or the UHF band (300 MHz to 3 GHz). Hereinbelow, it is assumed that the high-frequency power supply 71 outputs high-frequency power in the VHF band.

The outer conductor 62 is connected to the top surface of the lid 12. The central axis of the outer conductor 62 coincides with the central axis of the container main body 11. An inner diameter of the outer conductor 62 is substantially the same as a diameter of the through-hole 12a of the lid 12.

The film forming apparatus 1 further includes a waveguide 80. The waveguide 80 propagates the electromagnetic waves generated based on the high-frequency power from the high-frequency power supply 71 to the plasma processing space S. The waveguide 80 includes first to fourth waveguides 81 to 84.

The first waveguide 81 is defined by the outer peripheral surface of the inner conductor 61, the inner peripheral surface of the outer conductor 62, or the like, and propagates the electromagnetic waves in the axial direction (downward in the vertical direction) along the inner conductor 61.

The second waveguide 82 is continuous from the first waveguide 81 and is defined by the bottom surface of the lid 12 and the top surface of the shower head electrode 30. The second waveguide 82 propagates the electromagnetic waves outward in the horizontal direction along the radial direction in a plan view.

The third waveguide 83 is continuous from the second waveguide 82 and is defined by the outer peripheral surface of the shower head electrode 30 and the inner peripheral surface of the sidewall of the container main body 11. The third waveguide 83 propagates the electromagnetic waves in the axial direction (downward in the vertical direction) along the outer peripheral surface of the shower head electrode 30.

The fourth waveguide 84 is continuous from the third waveguide 83 and is provided with the dielectric window 40. The fourth waveguide 84 propagates the electromagnetic waves, which have propagated through the third waveguide 83, to the plasma processing space through the dielectric window 40. The fourth waveguide 84 is defined by, for example, the outer peripheral surface of the shower head electrode 30 and the inner peripheral surface of the sidewall of the container main body 11.

Each of the first to fourth waveguides 81 to 84 is formed in an annular shape in a plan view. The third and fourth waveguides 83 and 84 located at the end of the waveguide 80 on the plasma processing space S side are provided to surround the outer periphery of the shower head electrode 30.

In the film forming apparatus 1, plasma is generated in the plasma processing space S by the electromagnetic waves propagated through the dielectric window 40. In order to draw ions and the like in the plasma into the wafer W, for example, a high-frequency power for RF bias may be electrically connected to the stage 20 via a matcher. The high-frequency power supply for RF bias outputs high-frequency power of, for example, 400 kHz to 20 MHz.

The film forming apparatus 1 includes a controller U. The controller U is configured with, for example, a computer including a CPU, a memory, or the like, and includes a program storage part (not illustrated). A program is stored in the program storage part to control the high-frequency power supply 71 and the like for various processes in the film forming apparatus 1. The program may be recorded in a computer-readable storage medium and may be installed in the controller U from the storage medium.

Furthermore, the film forming apparatus 1 is provided with three or more pins 90 to protrude into the waveguide 80. In this example, it is assumed that the number of pins 90 is eight.

Each of the pins 90 is provided to protrude into the waveguide 80 from the inner peripheral surface of the film forming apparatus 1 that forms the waveguide 80. Specifically, as illustrated in FIG. 4, each of the pins 90 is provided to protrude horizontally from the inner peripheral surface of the sidewall of the container main body 11 into the third waveguide 83. More specifically, the protruding direction of the pins 90 is the radial direction about the central axis of the processing container 10 in a plan view. Although the pins 90 are provided to protrude, the pins do not electrically short the wall surfaces forming the waveguide 80 (specifically, the outer peripheral surface of the shower head electrode 30 and the inner peripheral surface of the sidewall of the container main body 11). The pins 90 protrude into the waveguide 80 in such a manner that no electrical short circuit occurs between the wall surfaces forming the waveguide 80.

The pins 90 are made of a conductive material, specifically, a metal material such as aluminum. The pins 90 are formed, for example, in the shape of a rod, and specifically, in a columnar shape having a spherical tip end. Protrusion amounts of the pins 90 from the inner peripheral surface of the sidewall of the container main body 11 are 1 mm to 48 mm. From the viewpoint of preventing discharge, the tip ends of the pins 90 need to be separated from the outer peripheral surface of the shower head electrode 30 by 2 mm or more. In addition, the distance between the inner peripheral surface of the sidewall of the container main body 11 and the outer peripheral surface of the shower head electrode 30 is 10 mm to 50 mm.

The pins 90 are used by being inserted through, for example, lateral holes 11b provided in the sidewall of the container main body 11. The pins 90 are fixed to the sidewall of the processing container 10 and electrically connected to the processing container 10 by brazing the pins 90 in the state of being inserted through the lateral holes 11b. As described above, since the processing container 10 is grounded, the pins 90 also have a ground potential.

As illustrated in FIG. 5, the pins 90 are arranged at positions separated from each other along the circumferential direction about the central axis of the processing container 10 in a plan view. More specifically, the pins 90 are arranged at equal intervals along the circumferential direction in a plan view.

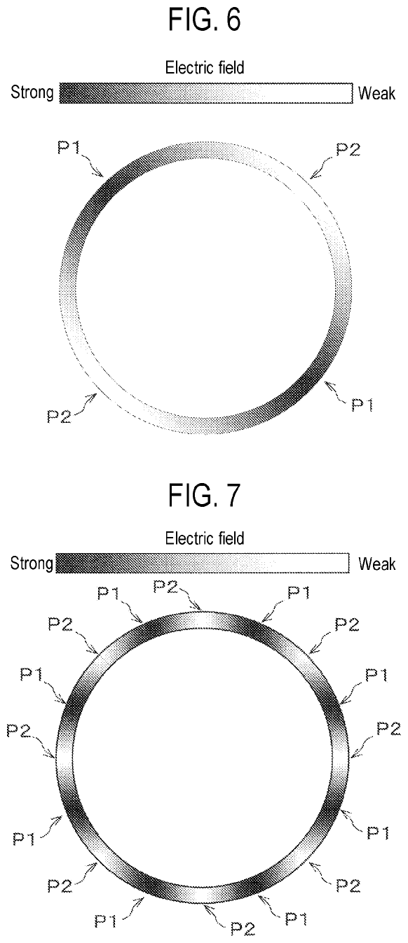

Here, the effects of the pins 90 will be explained. FIGS. 6 and 7 are views schematically illustrating electric field strength distributions of electromagnetic waves propagated inside the plasma processing space S under the dielectric window 40, in which FIG. 6 illustrates a distribution in a case in which the pins 90 are not provided, and FIG. 7 illustrates a distribution in the case in which the pins 90 are provided.

The following description is based on the premise that the distance between the stage 20 and the shower head electrode 30 is large in a plasma processing apparatus such as a film forming apparatus 1 that uses high-frequency power in the VHF band or the like for plasma generation.

The waveguide 80 of the film forming apparatus 1 is pseudo-similar to a coaxial cable. A cutoff frequency Fc of the coaxial cable may be expressed by Equation 1 below. In Equation 1, d is a diameter of the inner conductor of the coaxial cable, D is an inner diameter of the outer conductor, and εr is a relative permittivity of an insulator interposed between the inner conductor and the outer conductor.

$$\begin{matrix}[ Equation 1 ] & \\ F c = \frac{11.8}{\sqrt{{ε}_{r}} x π x ( \frac{D + d}{2} )} & ( 1 )\end{matrix}$$

When the third and fourth waveguides 83 and 84 in the vicinity of the peripheral edge of the shower head electrode 30 of the waveguide 80 are regarded as coaxial cables, the diameter of the shower head electrode 30 corresponds to the diameter d of the internal conductor, and the inner diameter of the sidewall of the container main body 11 corresponds to the inner diameter D of the outer conductor. Since the wafer W is large, the diameter of the shower head electrode 30 corresponding to the diameter d of the inner conductor and the inner diameter of the sidewall of the container main body 11 corresponding to the inner diameter D of the outer conductor are also large. Therefore, as is clear from Equation 1, when the third and fourth waveguides 83 and 84 are regarded as coaxial cables, a cutoff frequency Fc thereof is small. In contrast, the frequency of the electromagnetic waves propagating in the waveguide 80 is high and exceeds this cutoff frequency Fc. Therefore, in the waveguide 80, a higher-order mode may exist in addition to the TEM mode.

Therefore, when the pins 90 are not provided, the magnitudes of the electric fields of the electromagnetic waves propagated in the plasma processing space S through the dielectric window 40 are not uniform in the circumferential direction, and for example, as illustrated in FIG. 6, strong electric field portions P1 and weak electric field portions P2 occur alternately twice along the circumferential direction.

In addition, the plasma density is high in the portions having a strong electric field, and the plasma density is low in the portions having a weak electric field. Therefore, when the pins 90 are not provided, high plasma density regions and low plasma density regions occur alternately twice along the circumferential direction in the vicinity of the dielectric window 40 of the plasma processing space S, that is, in the vicinity of the peripheral edge of the shower head electrode 30.

In the vicinity of the peripheral edge of the shower head electrode 30, the number of high plasma density regions and low plasma density regions, which occur alternately along the circumferential direction (hereinafter, the number of occurrences of the high and low plasma density regions), is as small as two, and the distance between the high plasma density regions and the low plasma density regions is large. Therefore, even if the distance between the shower head electrode 30 and the stage 20 is large and the plasma generated in the vicinity of the shower head electrode 30 is diffused and reaches the vicinity of the stage 20, the distribution of the plasma density does not change so much in the vicinity of the shower head electrode 30 and in the vicinity of the stage 20. Therefore, when the pins 90 are not provided, a film formed by the film forming apparatus may have a film thickness distribution in the double symmetry relationship, as illustrated in FIG. 1.

In contrast, the film forming apparatus 1 is provided with eight pins 90 protruding into the waveguide 80. Therefore, the magnitudes of the electric fields of the electromagnetic waves propagated to the plasma processing space S through the dielectric window 40 are not uniform in the circumferential direction as in the case in which the pins 90 are not provided, in which, as illustrated in FIG. 7, strong electric field portions P1 and weak electric field portions P2 are alternately generated eight times along the circumferential direction. That is, in the film forming apparatus 1, the number of occurrences of the high and low plasma density regions is as high as 8 times in the vicinity of the dielectric window 40 of the plasma processing space S, that is, in the vicinity of the peripheral edge of the shower head electrode 30. Therefore, in the vicinity of the peripheral edge of the shower head electrode 30, the distance between the high plasma density regions and the low plasma density regions is small. Therefore, when the plasma generated in the vicinity of the shower head electrode 30 is diffused and reaches the vicinity of the stage 20 due to the large distance between the shower head electrode 30 and the stage 20, the variation in the plasma density in the circumferential direction is reduced in the vicinity of the stage 20, and the plasma density becomes uniform in the plane. Therefore, a film formed in the film forming apparatus 1 has a uniform thickness in the plane.

In order to improve the film thickness distribution in the double symmetry relationship, the number of occurrences of the high and low plasma density regions needs to be three or more in the vicinity of the peripheral edge of the shower head electrode 30 of the plasma processing space S. Therefore, three or more pins 90 are required.

Meanwhile, in order to improve the one-sided film thickness distribution as illustrated in FIG. 2, two or more pins 90 are required. The reason will be explained below.

When a one-sided film thickness distribution occurs, it means that, when the pins 90 are not provided, the number of occurrences of the high and low plasma density regions is one in the vicinity of the peripheral edge of the shower head electrode 30 of the plasma processing space S. When the number of occurrences of the high and low plasma density regions in the vicinity of the peripheral edge of the shower head electrode 30 of the plasma processing space S is set to 2 or more by providing the pins 90, compared to the case in which the pins 90 are not provided, the distance between the high plasma density regions and the low plasma density regions becomes smaller and the variation in plasma density in the vicinity of the stage 20 is reduced. The number of appearances of the high and low plasma density regions coincides with the number of pins 90. Therefore, in order to improve the one-sided film thickness distribution as illustrated in FIG. 2, two or more pins 90 are required.

Next, a wafer processing in the film forming apparatus 1 will be described.

First, the wafer W is carried into the processing container 10 and placed on the stage 20. Then, the interior of the processing container 10 is evacuated by an exhaust device (not illustrated), and a pressure in the plasma processing space S is adjusted to a predetermined pressure.

Thereafter, a plasma processing gas is supplied from the gas source 50 to the plasma processing space S via the gas diffusion chamber 31 of the shower head electrode 30 and the like at a predetermined flow rate. The plasma processing gas contains, for example, an excitation gas such as an Ar gas, a nitrogen gas and a silane gas for forming a SiN film, or the like.

Subsequently, high-frequency power in the VHF band is supplied from the high-frequency power supply 71 to the shower head electrode 30. In addition, the electromagnetic waves generated based on the high-frequency power propagate in the waveguide 80 and are supplied to the plasma processing space S through the dielectric window 40.

Since the pins 90 are arranged in the waveguide 80 at positions separated from each other along the circumferential direction in a plan view, the density of plasma generated by the electromagnetic waves supplied to the plasma processing space S becomes uniform in the plane of the wafer W in the vicinity of the stage 20, as described above. In this way, the wafer W is processed by plasma having a density uniform in the plane. Therefore, a SiN film having a film thickness uniform in the plane is formed on the wafer W. In addition, a refractive index of the formed SiN film also becomes uniform in the wafer plane.

When the film formation is completed, the supply of the plasma processing gas from the gas source 50 and the supply of the high-frequency power in the VHF band from the high-frequency power supply 71 are stopped. Thereafter, the wafer W is carried out from the processing container 10, and the wafer processing is completed.

As described above, in the present embodiment, the film forming apparatus 1 includes the stage 20 on which the wafer W is placed, the shower head electrode 30 which is disposed at a position facing the stage 20 and to which the high-frequency power in the VHF band is supplied, and the waveguide 80 configured to propagate electromagnetic waves generated based on the high-frequency power to the plasma processing space S formed between the stage 20 and the shower head electrode 30. In addition, the end of the waveguide 80 on the plasma processing space S side is formed in an annular shape in a plan view to surround the outer periphery of the shower head electrode 30, and the plurality of pins 90 are provided to protrude into the waveguide 80. The pins 90 are provided at respective positions separated from each other along the circumferential direction in a plan view. Therefore, when the film thickness distribution D1 in the double symmetry relationship as illustrated in FIG. 1 and the one-sided film thickness distribution D2 as illustrated in FIG. 2 occur when the pins 90 are not provided (that is, when the plasma density becomes in-plane non-uniform in the vicinity of the stage 20 to the extent that such film thickness distributions occur when the pins 90 are not present), it is possible to make the plasma density in the vicinity of the stage 20 uniform in the plane of the wafer with the pins 90. As described above, according to the present embodiment, when film formation is performed with plasma generated based on high-frequency power of 30 MHz or higher, it is possible to improve uniformity in the film forming results in the circumferential direction and the like.

According to the present embodiment, it is possible to improve the uniformity in the film forming results in the circumferential direction and the like without rotating the wafer W. Therefore, it is possible to reduce a cost compared with the case in which the rotation mechanism for the wafer W is provided. In addition, the processing results are not degraded by particles generated by the driving of the rotation mechanism.

When plasma processing results are biased concentrically, it may be dealt with by adjusting the processing conditions such as adjusting the amounts of the plasma processing gas inside and outside the wafer W. However, it is difficult to eliminate the circumferential bias in the double symmetry relationship and the one-sided bias by adjusting the processing conditions as described above.

It is preferable to arrange the pins 90 at equal intervals along the circumferential direction in a plan view. By setting the intervals to be equal along the circumferential direction, it is possible to reduce the distance between the high plasma density regions and the low plasma density regions in the vicinity of the peripheral edge of the shower head electrode 30 regardless of the number of pins 90. Thus, it is possible to more reliably improve the uniformity of the film forming results regarding the circumferential direction or the like.

When the pins 90 are arranged at equal intervals along the circumferential direction in a plan view, the intervals at which the pins 90 are provided do not have to be exactly the same as long as the variation in the plasma density in the circumferential direction can be reduced in the vicinity of the stage 20 and the uniformity of the film forming results can be improved.

In addition, all the pins 90 have the same protrusion amount. In other words, it is not necessary to adjust the protrusion amount for each pin 90. In this way, it is possible to improve the uniformity of the film forming results in the circumferential direction and the like without adjusting the protrusion amount for each pin 90.

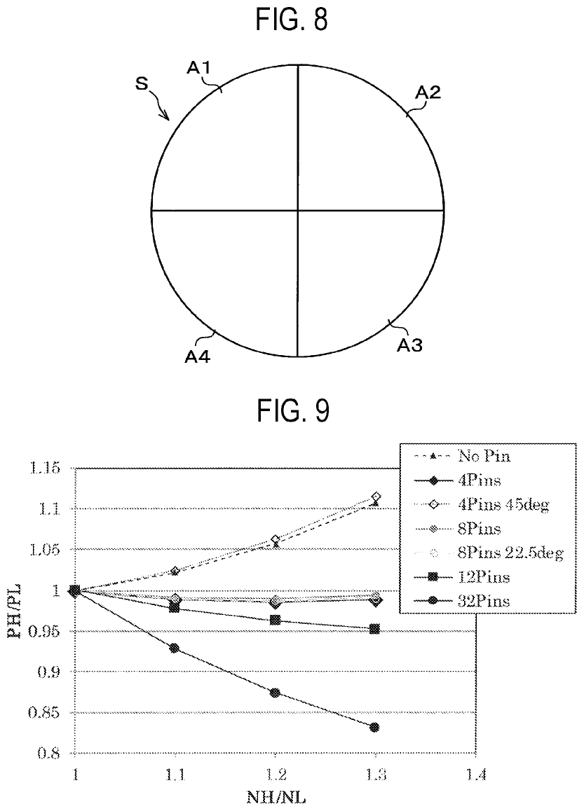

Next, the results of a simulation performed by the present inventors on the effects of the pins 90 will be described. FIG. 8 is a top view of the plasma processing space S, illustrating simulation conditions.

In the simulation, as illustrated in FIG. 8, the plasma processing space S was assumed to be cylindrical. Hereinafter, when the plasma processing space S is divided into four portions along the circumferential direction, regions A1 and A3 facing each other at one side will be referred to as low electron density regions, and regions A2 and A4 facing each other at the other side will be referred to as high electron density regions.
Fundamental conditions of the simulation are as follows.
Diameter of wafer W: 300 mm
Diameter of shower head electrode 30: 390 mm
Inner diameter of processing container 10: 430 mm
Frequency of high-frequency power supplied to shower head electrode 30: 220 MHz
Pressure of plasma processing space S: 100 Torr
Protrusion amount of pins 90: 17 mm
Intervals of pins 90: Equal interval

FIG. 9 is a view illustrating simulation results on an effect of the number of pins 90 and the arrangement angle of the pins 90.

In the drawing, the horizontal axis represents the value of a ratio (NH/NL) of the electron density of the high electron density regions A2 and A4 (NH) to the electron density of the low electron density regions A1 and A3 (NL). In addition, making the value of the electron density ratio (NH/NL) larger than 1 means making the plasma density symmetrical twice. The vertical axis represents the value of a ratio (PH/PL) of the power of electromagnetic waves input to the high electron density regions A2 and A4 (PH) to the power of electromagnetic waves input to the low electron density regions A1 and A3 (PL) when high frequency power is supplied to the shower head electrode 30.

As shown in the drawing, in the case in which the pins 90 are not provided (in the case of “No Pin”), as the value of the electron density ratio (NH/NL) increases, the value of the power ratio of electromagnetic waves (PH/PL) also increases. That is, in the case the pins 90 are not provided, as the plasma density in the plasma processing space S becomes non-uniform, electromagnetic waves are supplied to the plasma processing space S such that the plasma density becomes more non-uniform, in other words, such that the non-uniformity of the plasma density is promoted.

Meanwhile, in the case where eight pins 90 are provided (in the case of “8 Pins” and “8 Pins 22.5 deg”), twelve pins are provided (in the case of “12 Pins”), or thirty-two pins are provided (in the case of “32 Pins”), as the value of the electron density ratio (NH/NL) increases, the value of the power ratio of electromagnetic waves (PH/PL) decreases. That is, in the case where eight or more pins 90 are provided, when the plasma density in the plasma processing space S becomes non-uniform, electromagnetic waves are supplied to the plasma processing space S such that the plasma density becomes uniform.

In the case where four pins 90 are provided, when the arrangement angle of the pins 90 is (45+n×90) degrees (n is an integer from 0 to 3) when the boundary between the low electron density region A1 and the high electron density region A2 is 0 degrees (in the case of “4 Pins”), as the value of the electron density ratio (NH/NL) increases, the value of the power ratio of electromagnetic waves (PH/PL) decreases. However, in the case where four pins 90 are provided, when the arrangement angle of the pins 90 is shifted by 45 degrees from the state of “4 Pins” (in the case of “4 Pins 45 deg”), that is, when the pins 90 are provided at the boundaries between the low electron density regions and the high electron density regions, as the value of the electron density ratio (NH/NL) increases, the power ratio of electromagnetic waves (PH/PL) also increases, as in the case where the pins 90 are not provided.

In contrast, in the case where eight pins 90 are provided, when the arrangement angle of the pins 90 is (22.5+m×45) degrees (m is an integer of 0 to 7) (in the case of “8 Pins”), as the value of the electron density ratio (NH/NL) increases, the value of the power ratio of electromagnetic waves (PH/PL) decreases. In the case where eight pins 90 are provided, when the arrangement angle of the pins 90 is shifted by 22.5 degrees from the state of the above-mentioned “8 Pins” (in the case of “8 Pins 22.5 deg”), that is, when the pins 90 are also provided at boundaries between the low electron density regions and the high electron density regions, the power ratio of electromagnetic waves (PH/PL) also decreases as the electron density ratio value (NH/NL) increases.

That is, by setting the number of pins 90 to eight or more, it is possible to ensure improvement of non-uniformity in the plasma density in the plasma processing space S regardless of the arrangement angle of the pins 90.

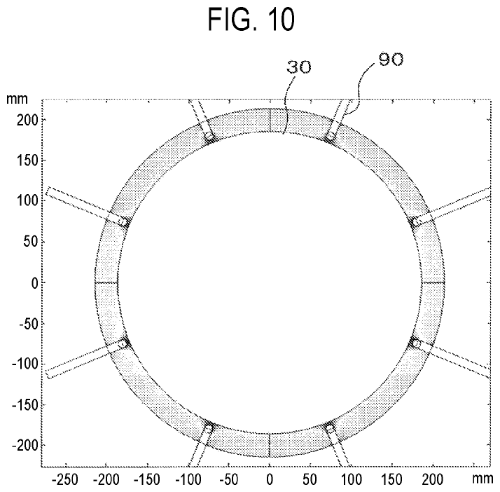

FIG. 10 is a view illustrating simulation results of an electric field distribution at the pin 90 arrangements positions.

FIG. 10 shows the results when the above-mentioned value of electron density ratio (NH/NL) is 1.3 and the number of pins 90 is eight. In FIG. 10, the strengths of electric fields are shown by the shade of color, in which the stronger the electric field, the darker the color.

By providing the pins 90, the electric fields are concentrated near the tips of the pins 90 as shown in the drawing.

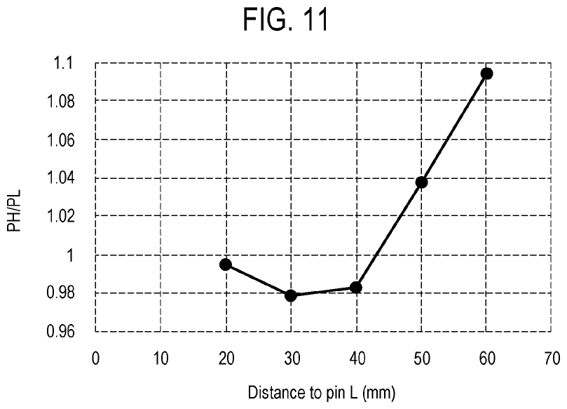

FIG. 11 is a view illustrating simulation results on an effect of the path length from the plasma processing space S to the pins 90.

FIG. 11 shows the results when the above-mentioned value of electron density ratio (NH/NL) is 1.3 and the number of pins 90 is eight.

In FIG. 11, the horizontal axis represents the path length L (see FIG. 4) from the plasma processing space S to the pins 90. Specifically, the path length is the length from the end surface of the dielectric window 40 on the plasma processing space S side to the pins 90, and more specifically, the length of connecting the center lines of the waveguides from the end surface of the dielectric window 40 on the plasma processing space S side up to the pins 90. In FIG. 11, the vertical axis represents the above value of the power ratio of electromagnetic waves (PH/PL).

As shown in FIG. 11, when the path length L is 40 mm or less, the value of the power ratio of electromagnetic waves (PH/PL) is less than 1. That is, when the path length L is 40 mm or less, it is possible to ensure improvement of the non-uniformity of the plasma density in the plasma processing space S by providing the pins 90.

In addition, when the path length L is 50 mm, the value of the power ratio of electromagnetic waves (PH/PL) is 1.04. At a glance, this result seems to be unfavorable because the deviation of the plasma density in the plasma processing space S is promoted when the path length L is 50 mm, but this simulation result is a result for an extreme environment. Therefore, when the value of the power ratio of electromagnetic waves (PH/PL) is about 1.04, that is, when the path length L is 50 mm, in the actual environment, it is considered to work in the direction of eliminating the bias of the plasma density distribution.

Therefore, the path length L may be 50 mm or less.

The reason that the bias of the plasma density distribution cannot be eliminated even if the pins 90 are provided when the path length L becomes large is, for example, as follows. When the path length L increases, the effect of the pins 90 is weakened while the electromagnetic waves propagate to the dielectric window 40, and the electric field distribution by the pins 90 is weakened. Therefore, when the path or the like increases, the electromagnetic waves propagated to the plasma processing space S through the dielectric window 40 becomes the same as in the case in which the pins 90 are not provided. Therefore, it is considered that the bias of the plasma density distribution cannot be eliminated even if the pins 90 are provided.

In the above-described examples, the pins 90 are electrically connected to the ground potential, that is, the container main body 11 on the cold side, and protrude from the container main body 11. Instead of this, the pins may be electrically connected to the shower head electrode 30 on the hot side to which high-frequency power is supplied to protrude from the shower head electrode 30 side to the waveguide 80. In either case, the pins are provided so that the container main body 11 and the shower head electrode 30 are not electrically short-circuited via the pins, and no discharge occurs between the container main body 11 and the shower head electrode 30.

In addition, the pins are not electrically connected to either the container main body 11 or the shower head electrode 30, and may be electrically in a floating state.

In the above-described examples, the pins have been described to be made of a conductive material, but may be made of a dielectric material.

However, in order to ensure electric field concentration, the pins are preferably made of a conductive material and electrically connected to the container main body 11 on the cold side or the shower head electrode 30 on the hot side, without being electrically floated.

In the above-described examples, the pins 90 are provided in the third waveguide 83 of the waveguide 80. Instead of this, the pins may be provided in the second waveguide 82 or the fourth waveguide 84 of the waveguide 80.

In the above-described example, the protruding lengths of the pins are fixed. Instead of this, the protruding lengths of the pins 90 may be adjustable by forming female screws on the inner peripheral surfaces of the lateral holes 11b and forming male screws on the outer peripheral surfaces of the pins 90. In addition, the protruding lengths of the pins 90 may be adjusted in this way, and the pins 90 may be configured to protrude only when necessary.

In the foregoing, the film forming apparatus has been described as an example, but the technique according to the present disclosure is also applicable to a plasma processing apparatus performing a process other than the film forming process. For example, the technique according to the present disclosure is also applicable to a plasma processing apparatus that performs an etching process or a doping process as the plasma processing.

The embodiments disclosed herein should be considered to be exemplary in all respects and not restrictive. The embodiments described above may be omitted, replaced, or modified in various forms without departing from the scope and spirit of the appended claims

### EXPLANATION OF REFERENCE NUMERALS

1: film forming apparatus
20: stage
30: shower head electrode
80: waveguide
90: pin
S: plasma processing space
W: wafer

1. A plasma processing apparatus for processing an object to be processed with plasma, comprising:
a stage on which the object to be processed is placed;
an electrode arranged at a position facing the stage and to which high-frequency power having a frequency of 30 MHz or more is supplied; and
a waveguide configured to propagate electromagnetic waves generated based on the high-frequency power to a plasma processing space formed between the stage and the electrode,
wherein the waveguide is formed in an annular shape in a plan view so that an end portion of the waveguide near the plasma processing space surrounds an outer periphery of the electrode,
wherein a plurality of pins are provided to protrude into the waveguide, and wherein the plurality of pins are arranged at respective positions separated from one another along a circumferential direction in the plan view.

2. The plasma processing apparatus of claim 1, wherein the plurality of pins are arranged at equal intervals along the circumferential direction in the plan view.

3. The plasma processing apparatus of claim 2, wherein all of the plurality of pins have an equal protrusion amount.

4. The plasma processing apparatus of claim 3, wherein each of the plurality of pins is formed of a conductive material.

5. The plasma processing apparatus of claim 4, wherein a number of the plurality of pins is eight or more.

6. The plasma processing apparatus of claim 5, wherein a path length from the plasma processing space to the plurality of pins is 50 mm or less.

7. A plasma processing method of processing an object to be processed with plasma by using a plasma processing apparatus that includes a stage on which the object to be processed is placed, an electrode arranged at a position facing the stage and to which high-frequency power having a frequency of 30 MHz or more is supplied, and a waveguide configured to propagate electromagnetic waves generated based on the high-frequency power to a plasma processing space formed between the stage and the electrode, wherein an end portion of the waveguide near the plasma processing space is formed in an annular shape in a plan view to surround an outer periphery of the electrode, a plurality of pins are provided to protrude into the waveguide, and the plurality of pins are arranged at respective positions which are spaced apart from each other in a circumferential direction in the plan view,
the plasma processing method comprising:
supplying the high-frequency power to the electrode, propagating the electromagnetic waves generated based on the high-frequency power to the plasma processing space via the waveguide provided with the plurality of pins, and generating the plasma inside the plasma processing space; and
processing the object to be processed on the stage with the generated plasma.

8. The plasma processing apparatus of claim 1, wherein all of the plurality of pins have an equal protrusion amount.

9. The plasma processing apparatus of claim 1, wherein each of the plurality of pins is formed of a conductive material.

10. The plasma processing apparatus of claim 1, wherein a number of the plurality of pins is eight or more.

11. The plasma processing apparatus of claim 1, wherein a path length from the plasma processing space to the plurality of pins is 50 mm or less.
